(19) United States
(12) Patent Application Publication
(10) Pub. No.: US 2025/0264643 A1
(43) Pub. Date: Aug. 21, 2025

(54) MIRROR ELEMENT, LITHOGRAPHY SYSTEM, AND METHOD FOR PROVIDING A MIRROR ELEMENT

(71) Applicant: Carl Zeiss SMT GmbH, Oberkochen (DE)

(72) Inventor: Michael CARL, Aalen (DE)

(21) Appl. No.: 19/200,064

(22) Filed: May 6, 2025

Related U.S. Application Data
(63) Continuation of application No. PCT/EP2023/078296, filed on Oct. 12, 2023.

(30) Foreign Application Priority Data
Nov. 9, 2022 (DE) 10 2022 211 866.9

(51) Int. Cl. G02B 5/10; G02B 5/08; G03F 7/00

(52) U.S. Cl. CPC G02B 5/10; G02B 5/0891; G03F 7/7015; G03F 7/702; G03F 7/70233; G03F 7/70316; G03F 7/70504

(57) ABSTRACT

A mirror element (20) having a mirror surface (26) with an aspherical target region (22) and an extension region (28) adjoining an edge (24) of the target region (22) is disclosed, wherein the edge (24) is describable by an at least twice continuously differentiable closed curve (b), wherein the target region (22) has a respective edge curvature at each edge point(s) located on the curve, and wherein, when proceeding from the edge point(s) in a profile direction transverse to the edge (24), the extension region (28) has a curvature profile, which has no more than one local extremum and the absolute values of the curvatures of which are less than twice the absolute value of the edge curvature. Also disclosed are a lithography system (1) including a mirror element (20) and a method for providing a mirror element (20).

### CROSS-REFERENCE TO RELATED APPLICATION

This is a Continuation of International Application PCT/EP2023/078296, which has an international filing date of Oct. 12, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Applications DE 10 2022 211 866.9 filed on Nov. 9, 2022.

### FIELD

The present invention relates to a mirror element having a mirror surface which comprises a target region and an extension region adjoining an edge of the target region, to a lithography system comprising such a mirror element and to a method for providing such a mirror element.

### BACKGROUND

Microlithographic lithography systems are utilized for the production of integrated circuits with particularly small structures. A mask (reticle) illuminated by very short-wave deep ultraviolet or extreme ultraviolet radiation (DUV or EUV radiation) is imaged onto a lithography object in order to transfer the mask structure to the lithography object.

The lithography system comprises a plurality of mirrors at which the radiation is reflected. The mirrors have a precisely defined shape and are precisely positioned so that the imaging of the mask onto the lithography object is of sufficient quality.

The mirror surface of such a mirror comprises a zone where the very short-wave UV radiation is reflected during the operation of the lithography system. In this zone, which is referred to as the target region of the mirror surface, the shape of the mirror surface is specified by the wavefront of the radiation having a certain shape in the object plane. The manufacture of the mirror, which includes a polishing step amongst others, requires that the mirror surface be continued beyond the edge of the target region into an extension region. A sufficient surface quality at the edge of the target region can be achieved only if the entire circumference of the polishing tool can be guided beyond the edge of the target region.

A mathematical description of the surface profile of the surface is available for the target region. It is possible to extrapolate this mathematical description beyond the edge of the target region and thus define the shape of the extension region. It was found that this procedure might impair the surface quality at the edge of the target region. This is especially the case for surface profiles described by high-order polynomials where the absolute value of a curvature or a local astigmatism increases with the distance from the target region, making an accurate polish and hence the provision of a mirror surface with a sufficient surface quality more difficult.

Against the background of the aforementioned problems, an object of the present invention therefore lies in providing an improved mirror element, with which it is possible in particular to avoid an impairment of the surface quality at the edge of the target region.

Various formulations for addressing this object are set forth in the independent claims. The dependent claims relate to advantageous developments.

According to one formulation, a mirror element having a mirror surface comprising an aspherical target region and an extension region adjoining an edge of the target region is disclosed, wherein the edge is describable by an at least twice continuously differentiable closed curve, wherein the target region has a respective edge curvature at each edge point located on the curve, and wherein, when proceeding from the edge point in a profile direction transverse to the edge, the extension region has a curvature profile, which has no more than one local extremum and the absolute values of the curvatures of which are less than twice the absolute value of the edge curvature.

By way of example, a mirror element according to the invention is a mirror element which has a circular mirror surface comprising a non-rotationally symmetric target region, for use in an illumination optical unit or a projection optical unit of an EUV lithography system.

Firstly, some terms used in the context of the invention are explained hereinbelow:

The “principal curvatures” of a point are intended to be understood to mean the minimum value and the maximum value of the curvatures of the plane curves which arise from an intersection of the given surface with the plane determined by the surface normal vector and the tangential direction of the point. They are a measure for the extent to which the surface at this point bends by different absolute values in different directions. The associated tangential directions are referred to as “principal curvature directions”.

Proceeding from a point along a profile direction, the “curvature profile” should be understood to mean a profile of those curvatures which have an intersection curve corresponding to an intersection of the mirror surface with a plane spanned by the normal vector at the edge point and the profile direction.

The “target region” denotes a zone of the mirror surface provided as a used zone. The surface profile of the target region is describable by high-order polynomials, for example polynomials of order 20. At every point on the edge, the target region has an edge curvature which, in terms of absolute value, is intended to correspond to a maximum principal curvature at this point. These edge points are located on the curve describing the edge.

The “extension region” is arranged immediately adjacent to the target region. At the edge points, the transition from the target region to the extension region via the edge may have a profile which is without jumps and without kinks. For example, the surface profile of the mirror surface is at least twice continuously differentiable.

Embodiments of the invention provide an advantageous configuration of a mirror element which has a mirror surface comprising a target region and an extension region. When proceeding from the edge point in a profile direction transverse to the edge, the fact that the extension region has a curvature profile, which has no more than one local extremum and the absolute values of the curvatures of which are less than twice the absolute value of the edge curvature, allows the surface in the extension region to be largely homogeneous and allows the mean curvature, which is to say the addition of the two principal curvatures, and the astigmatism, which is to say the difference between the two principal curvatures, to have only long-wave variations. Consequently, the invention provides a mirror element for which a special configuration of the extension region makes it possible to particularly effectively avoid a reduction in the quality of the mirror surface in the target region in particular due to manufacturing reasons-especially from within the scope of the required polishing of the mirror surface.

According to an embodiment, the absolute values of the curvatures of the curvature profile are less than or equal to the edge curvature.

This can ensure that none of the absolute values of the curvatures that occur along the curvature profile within the extension region go beyond the absolute value of the edge curvature, enabling an even more homogeneous configuration of the surface of the extension region. Should the curvature profile have a local extremum, this local extremem is accordingly assumed to be at the edge point in this case.

For example, the curvature profile has principal curvatures, the absolute values of which are less than or equal to the edge curvature.

Such a restriction of the principal curvatures within a curvature profile can result in the values of the mean curvature and astigmatism in the extension region not exceeding the values present at the respective edge point. The absolute value of possible variations in the curvatures can thus be reduced.

The absolute values of the curvatures decrease over the curvature profile in an embodiment. The curvature profile can be monotonic as an alternative or in addition.

In this way, bothersome variations of the curvatures in the extension region can be limited in terms of their amplitude, or avoided, during the manufacture of the mirror element.

Alternatively, the curvatures can be constant over the curvature profile.

This allows the curvature profile along the profile direction in the extension region to be described as part of the one circular edge. Thus, in three dimensions, the surface profile of the extension body can be described as part of the surface of a torus. This allows a particularly simple determination of the surface profile of the extension region.

Alternatively, the curvature profile along the profile direction in the extension region can be described as part of a parabola. As a result, the surface profile of the extension region can be considered overall to be part of the surface of an elliptic paraboloid.

According to a further embodiment, the profile direction is perpendicular to the edge. In this case, the profile direction corresponds to a surface normal of the tangential surface at the edge point from which the considered curvature profile emanates.

As an alternative, the profile direction can follow a principal curvature direction of the edge point from which the considered curvature profile emanates.

By way of example, the curvature profile is without jumps in the extension region. The curvature profile is continuous in that case. This is especially the case if the surface profile of the mirror surface is at least twice continuously differentiable.

Thus, the curvature profile along a jump-free curve and the surface profile of the extension region can be described along a jump-free surface of a three-dimensional body. This can reduce the outlay for determining the surface profile of the extension region.

In a further embodiment, at least one part of the surface of an extension body in contact with the edge covers the extension region, wherein, for a plurality of edge points, the extension body has perpendicular to the edge a cross-sectional area which is spanned by a circular or parabolic contact area that is determinable for the edge point on the basis of a beam parameter, wherein the beam parameter describes a length of a beam emanating from the edge point in a beam direction running transversely, more particular perpendicularly, to the curve and completely covering the extension region in the beam direction.

This represents a possible description of the surface profile of the extension region.

Additionally, the contact area can be determined on the basis of an installation space condition or on the basis of an optimization of the curvature in the extension region. This can be implemented by complementing the surface description of the contact area by the addition of a complementing term. By way of example, a further optimization of the mirror surface in view of an astigmatism reduction may also be achieved by the addition of a complementing term.

Further complementing terms may be provided, in particular for minimizing a function of the following form:

$$S ( f ) = {\int }_{{D}_{e}} {( {κ}_{1} ( {f}^{′} , {f}^{″} ) - {κ}_{2} ( {f}^{′} , {f}^{″} ) - {a}_{0} )}^{2} + {b}_{0} ( \text{} {( {κ}_{1} ( {f}^{′} , {f}^{″} ) + {κ}_{2} ( {f}^{′} , {f}^{″} ) - {k}_{0} )}^{2} + {c}_{0} ( {κ}_{1}^{′2} ( {f}^{′} , {f}^{″} , {f}^{′′′} ) + ( {κ}_{2}^{′2} ( {f}^{′} , {f}^{″} , {f}^{′′′} ) ) {dV}_{g}$$

where f: Dₑ→R³, (x, y) [symbol] (x, y, z (x, y)) is the parameterization of the surface over its sag z in the extension region Dₑ, κ_{1,2} are the two principal curvatures of the target region, dV_{g} is the surface integration measure, and the values of f′, f″, f′″ are specified by the edge of the target region and its properties.

The curve describing the edge can be expanded in basis functions, for example Fourier components, in order to allow for an efficient optimization.

By way of example, the extension region extends at least 50 mm from the edge of the target region in a direction perpendicular to the edge. The dimensions of the extension region should be such that the entire circumference of the polishing tool can be guided beyond the end of the target region in each portion of the edge, without the polishing tool reaching the peripheral edge of the extension region. In individual cases, this may lead to the surface area of the extension region being greater than the surface area of the target region.

Moreover, the embodiments of invention disclose a lithography system comprising a mirror element according to the invention. In particular, this may relate to an EUV lithography system.

Therein, an object field in an object plane can be illuminated via an illumination system. The illumination system comprises a plurality of optical elements which image illumination radiation emitted by an exposure radiation source into an object field arranged in an object plane. In the lithography system, the object field can be imaged into an image plane via a plurality of optical elements using a projection system. By way of example, a mask (also referred to as reticle) arranged in an object plane can be imaged onto a light-sensitive layer of a wafer arranged in the image plane. In particular, a projection system should be understood to mean a system comprising a plurality of optical elements which are successively arranged in a beam path to shape radiation entering the projection system. The optical elements of the projection system, especially the entirety thereof, may be in the form of mirrors. This is especially helpful if the radiation source emits EUV radiation since EUV radiation is generally subject to high transmission losses. The transmission losses are avoided if the radiation is only reflected and not transmitted. The mirrors may be configured for a grazing incidence of the beam path.

It is understood that the illumination system and also the projection system may also comprise in particular a plurality of mirror elements according to the invention.

Moreover, embodiments of the invention disclose a method for providing a mirror element having a mirror surface which has an aspherical target region and an extension region adjoining an edge of the target region, comprising:
determining an at least twice continuously differentiable closed curve, describing the edge, in the extension region;
for each edge point located on the curve, determining a beam parameter describing a length of a beam emanating from the edge point in a beam direction running transversely, more particular perpendicularly, to the curve and completely covering the extension region in the beam direction;
on the basis of the beam parameter, determining a circular or parabolic contact area for each edge point;
determining an extension body which is in contact with the edge and which has, for each of the edge points, a cross-sectional area spanned by the determined contact areas;
manufacturing the mirror element, wherein at least one part of the surface of the extension body covers the extension region.

In an embodiment, determining the contact area is additionally dependent on an installation space condition or on an optimization of the curvature in the extension region.

Regarding the detailed explanation of further advantageous developments of the method, reference is made to the above-described developments of the apparatus. Likewise, the apparatus can be developed using further features which are described in the context of the method.

The above-described embodiments and configurations should be understood to be merely exemplary and are not intended to restrict the present invention in any way.

### BRIEF DESCRIPTION OF THE DRAWINGS

In exemplary fashion, the invention will be explained in detail below on the basis of advantageous embodiments, with reference being made to the attached drawings, in which:

FIG. 1 shows a schematic illustration of one exemplary embodiment of a lithography system;

FIG. 2 shows a schematic illustration of one exemplary embodiment of a mirror element;

FIG. 3 shows a schematic illustration of exemplary adapted coordinates for providing a mirror element according to one exemplary embodiment;

FIG. 4 shows a schematic illustration of exemplary contact areas for providing a mirror element according to one exemplary embodiment;

FIG. 5 shows a schematic illustration of a portion of an exemplary extension body for providing a mirror element according to one exemplary embodiment; and

FIG. 6 shows an illustration of properties of a mirror surface of a mirror element according to one exemplary embodiment.

### DETAILED DESCRIPTION

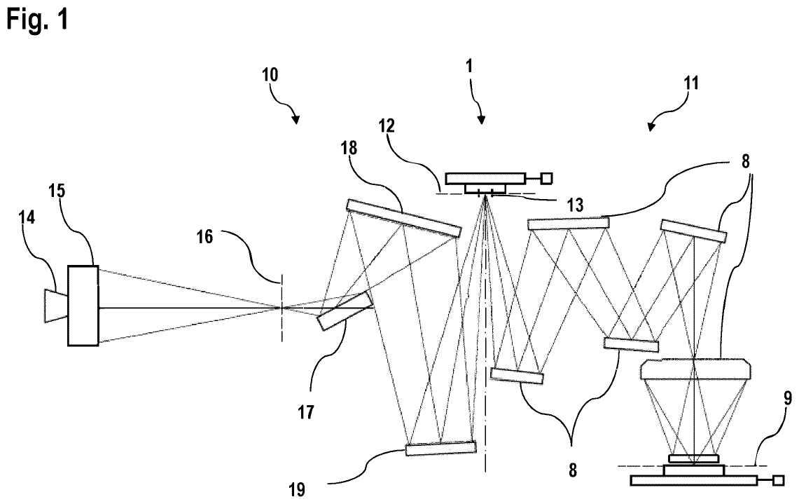

As an exemplary embodiment of a lithography system, FIG. 1 schematically illustrates an EUV lithography system 1. The EUV lithography system 1 comprises an illumination optical unit 10 and a projection optical unit 11. An object field 13 in an object plane 12 is illuminated by the illumination optical unit 10.

The illumination optical unit 10 comprises an illumination radiation source 14 which emits electromagnetic radiation in the EUV range, which is to say at a wavelength of between 5 nm and 100 nm in particular. The illumination radiation emanating from the illumination radiation source 14 is first focused into an intermediate focus plane 16 by a collector 15.

The illumination optical unit 10 comprises a deflection mirror 17, with which the illumination radiation emitted by the illumination radiation source 14 is deflected to a first facet mirror 18. A second facet mirror 19 is disposed downstream of the first facet mirror 18. The first facet mirror and the second facet mirror 19 each comprise a multiplicity of micromirrors that are pivotable on an individual basis about two respective axes which run perpendicular to one another. The individual facets of the first facet mirror 18 are imaged into the object field 13 using the second facet mirror 19.

With the projection optical unit 11, the object field 13 is imaged into an image plane 9 using a plurality of mirrors 8. Arranged in the object plane 12 is a mask (also called reticle) which is imaged onto a light-sensitive layer of a wafer arranged in the image plane 9. The various mirrors of the EUV lithography system 1 at which the illumination radiation is reflected take the form of EUV mirrors. The EUV mirrors have been provided with highly reflective coatings, for example in the form of multilayer coatings, especially with alternating layers of molybdenum and silicon.

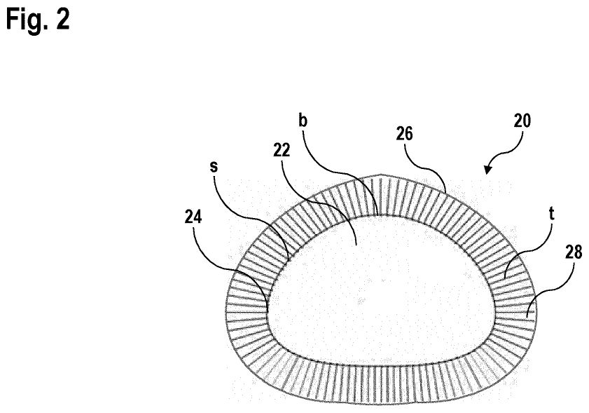

FIG. 2 schematically illustrates a mirror element 20 in a plan view, the mirror element for example being a mirror 8 of the projection optical unit 11 of the EUV lithography system 1. However, it is also feasible that the mirror element 20 is a component of the mirrors in the illumination optical unit 10. The mirror element 20 comprises a mirror surface 26 which has a target region 22 and an extension region 28 adjoining an edge 24 of the target region. A twice continuously differentiable closed curve b, on which a plurality of edge points s are located, can be used to describe the edge 24. The target region 22 has a respective edge curvature at each edge point s. When proceeding from the edge point s in a profile direction transverse to the edge 24, the extension region 28 has a curvature profile, the absolute values of the curvatures of which are less than or equal to the edge curvature. Likewise, the curvature profile has principal curvatures, the absolute values of which are less than or equal to the edge curvature. Accordingly, the mean curvature and the astigmatism of the curvature profile are no greater than at the edge point(s).

An exemplary provision of such a mirror element 20 is described below with reference to FIGS. 2 to 5.

The closed curve b describing the edge 24 should be determined first, for example in Cartesian coordinates, as shown in FIG. 2. Should it not be possible to describe the actual edge of the target region 22 by the curve b, for example because it is not free from jumps or kinks, it would also be feasible for the actual edge of the target region 22, for example a convex envelope of the actual edge, to be approximated by the curve b in the extension region 28.

The curve b is parameterized according to the arc length, wherein the curve b is represented by B-splines of polymer order 5 whilst taking into account a suitable smoothing parameter. The smoothing parameter is defined on the basis of the strength of the bends of the curve b, which is to say the curvature of the curve b. In one variant, the curve b can also be represented by low pass-filtered Fourier expansions of the edge 24.

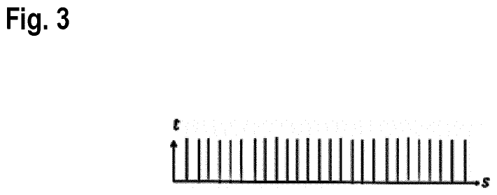

The representation of the determined curve b is transferred into an adapted coordinate system. By way of example, there can be a transformation from Cartesian coordinates to generalized polar coordinates, in which the curve b is parameterized by the edge points s and a second coordinate t represents a beam for each edge point s, said beam being transverse to the edge 24 at each edge point s and covering the extension region 28. An illustration of the result of such a coordinate transformation, applied to the example in FIG. 2, is shown in FIG. 3. The coordinate transformation is at least twice continuously differentiable, for example at least three times. In the shown example of FIGS. 2 and 3, the beams t for the edge points s are each perpendicular to the edge 24.

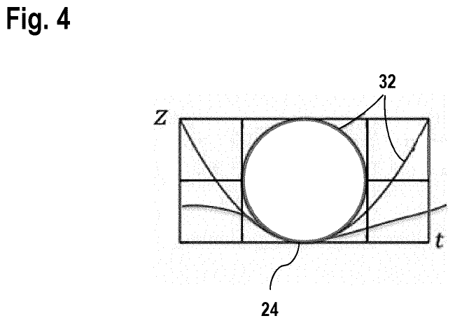

Respective contact areas 32, which contact the edge 24 at the edge point s, are formed along the beams t for the edge points s. The contact areas 32 can be circular or parabolic, as indicated in FIG. 4, or else have a shape according to a higher polynomial order. When a parabolic contact area is used, the latter should be configured so that its maximum curvature is at the edge point s.

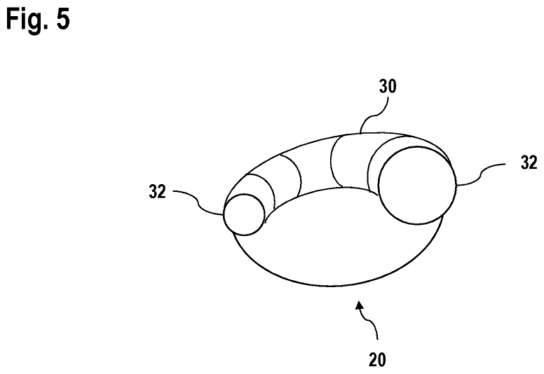

When interpolating the intermediate space between two contact areas 32 which is located between two edge points s, this yields an extension body 30 in contact with the edge 24, with a part of the surface of this extension body covering the extension region 28. A schematic illustration of a portion of an exemplary extension body 30 is illustrated in FIG. 5. All contact areas 32 of the extension body 30 have a circular shape in the example shown. Accordingly the extension body has a toroidal shape. The description of the surface zₑ in the extension region 28 is then given by the formula:

$${Z}_{e , torish} ( t , s ) = z ( 0 , s ) + {κ}^{- 1} ( s ) ( \sqrt{1 - {( κ ( s ) x - {n}_{1} ( s ) )}^{2}} - \sqrt{1 - {n}_{1}^{2} ( s )} )$$

Here, the parameters κ(s) and n1(s) are determined by a twice continuous differentiability of the surface profile of the mirror surface.

In this way, proceeding in a profile direction transverse to the edge 24 from the edge point s, the extension region 28 has a curvature profile, the absolute value of the maximum curvature of which equals the edge curvature of the edge point s. The curvatures in the curvature profile are constant, and consequently also have the same sign. In the presented example, the edge curvature for the respectively considered edge point s corresponds to the inverse radius of the circular contact area 32. By contrast, the curvatures in the curvature profile would have the same sign but decrease in terms of absolute value if a parabolic contact area were used.

In the present example, the description of the surface zₑ in the extension region 28 is additionally adapted in order to be able to satisfy an installation space condition specified for the mirror element 20. The description of the surface zₑ is complemented by the addition of the term Σᵢ₌₀^{N}cᵢ(s)Hᵢ(t), where Hᵢ represents at least twice continuously differentiable functions, for which the condition Hᵢ(0)=H′ᵢ(0)=0 applies. The coefficients cᵢ(s) are determined by an optimization that depends on the specified installation space condition. The coefficients cᵢ(s) are expanded in a Fourier series and can be set to 0 above a Fourier order M, corresponding to low-pass filtering. As a result, by virtue of only N*M parameters effectively needing to be taken into account, it is possible to reduce the outlay for additionally taking account of the complement.

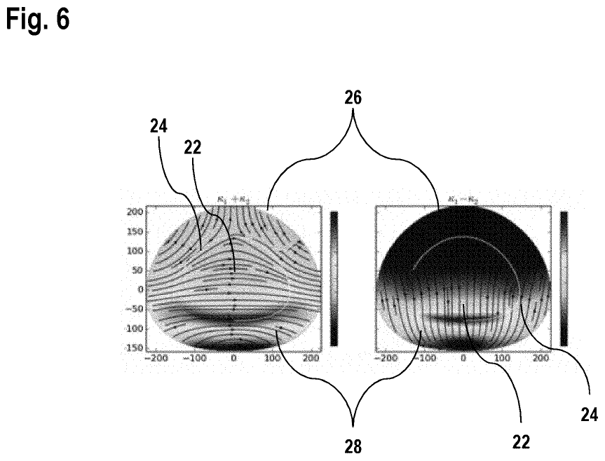

Properties of a mirror surface 26 of a mirror element 20 provided in the manner described are shown in FIG. 6 on the basis of two graphs. The target region 22 and the extension region 28 adjoining the edge 24 of the target region 22 are also illustrated. In the two graphs, the x- and y-axes denote positions on the mirror surface 26 in the x-(right/left) and in the y-(up/down) direction in mm. The plotted flow lines correspond to the respective principal curvature directions.

The intensity of the shading in the graph on the left-hand side reproduces the value of the addition of the two principal curvatures κ₁+κ₂ for the points of the mirror surface 26. It is evident that the addition of the principal curvatures has high values, especially for points on the edge 24 at the lower end of the target region 22. However, when respectively proceeding from the points on the edge 24, the value in the extension region 28 reduces in a direction transverse to the edge 24 as a matter of principle.

In the graph on the right-hand side, the intensity of the shading reproduces the value of the subtraction of the two principal curvatures κ₁-κ₂, corresponding to the astigmatism, for the points of the mirror surface 26. This value, too, is large for points on the edge 24 at the lower end of the target region 22 but, when proceeding from the points on the edge 24, as a matter of principle reduces once again in the extension region 28 in a direction transverse to the edge 24.

From the fact that the values of both the addition and the subtraction of the two principal curvatures reduce in the extension region 28 when respectively proceeding from the points on the edge 24 in a direction transverse to the edge 24, it is evident that the provided mirror element 20 has a mirror surface 26 in which the extension region 28 has, respectively proceeding from each considered point on the edge 24 in a direction perpendicular to the edge 24, a maximum curvature which in terms of absolute value is less than or equal to the edge curvature.

The embodiments of the present invention described in this specification and the optional features and properties respectively listed in this respect should also be understood as disclosed in all combinations with one another. In particular, the description of a feature comprised by an embodiment-provided there are no explicit explanations to the contrary-should also not be construed in the present case as meaning that the feature is indispensable or essential to the function of the embodiment.

What is claimed is:

1. Mirror element having a mirror surface that comprises an aspherical target region and an extension region adjoining an edge of the target region,
wherein the edge is describable by an at least twice continuously differentiable closed curve,
wherein the target region has a respective edge curvature at each of the edge points located on the curve,
wherein, when proceeding from a respective one of the edge points in a profile direction transverse to the edge, the extension region has a curvature profile, which has no more than one local extremum and the absolute values of the curvatures of which are less than twice the absolute value of the edge curvature,
and wherein the target region is describable by high-order polynomials where the absolute value of a curvature or a local astigmatism increases with the distance from the target region.

2. Mirror element according to claim 1, wherein the absolute values of the curvatures of the curvature profile are less than or equal to the edge curvature.

3. Mirror element according to claim 1, wherein the curvature profile has principal curvatures, the absolute values of which are less than or equal to the edge curvature.

4. Mirror element according to claim 1, wherein the absolute values of the curvatures decrease over the curvature profile.

5. Mirror element according to claim 1, wherein the curvature profile is monotonic.

6. Mirror element according to claim 1, wherein the curvatures are constant over the curvature profile.

7. Mirror element according to claim 1, wherein the profile direction is perpendicular to the edge.

8. Mirror element according to claim 1, wherein the curvature profile is without jumps in the extension region.

9. Mirror element according to claim 1, wherein at least one part of a surface of an extension body in contact with the edge covers the extension region, wherein, for a plurality of edge points, the extension body has perpendicular to the edge a cross-sectional area which is formed by a circular or parabolic contact area that is determinable for the edge point based on a beam parameter, wherein the beam parameter describes a length of a beam emanating from the edge point in a beam direction running transversely to the curve and completely covering the extension region in the beam direction.

10. Mirror element according to claim 9, wherein the beam direction runs perpendicularly to the curve.

11. Mirror element according to claim 9, wherein the contact area is determinable based on an installation space condition or an optimization of the curvature in the extension region.

12. Mirror element according to claim 1, wherein the target region is not rotationally symmetric.

13. Mirror element according to claim 1, wherein the extension region extends at least 50 mm from the edge of the target region in a direction perpendicular to the edge.

14. Mirror element according to claim 1, wherein the extension region has a larger area than the target region.

15. Lithography system, comprising:
an illumination system comprising a plurality of optical elements arranged to image illumination radiation emitted by an exposure radiation source into an object field arranged in an object plane; and
a projection system comprising a further plurality of optical elements arranged to image the object field into an image field arranged in an image plane;
wherein at least one of the illumination system and the projection system comprises at least one mirror element according to claim 1.

16. Method for providing a mirror element having a mirror surface which has an aspherical target region and an extension region adjoining an edge of the target region, wherein the target region is describable by high-order polynomials where the absolute value of a curvature or a local astigmatism increases with the distance from the target region, comprising:
determining an at least twice continuously differentiable closed curve, describing the edge, in the extension region;
for each edge point located on the curve, determining a beam parameter describing a length of a beam emanating from the edge point in a beam direction running transversely to the curve and completely covering the extension region in the beam direction;
based on the beam parameter, determining a circular or parabolic contact area for each edge point;
determining an extension body which is in contact with the edge and which has, for each of the edge points, perpendicular to the edge a cross-sectional area formed by the determined contact areas;
manufacturing the mirror element, wherein at least one part of the surface of the extension body covers the extension region.

17. Method according to claim 16, wherein the beam direction runs perpendicularly to the curve.

18. Method according to claim 16, wherein determining the contact area is additionally dependent on an installation space condition or on an optimization of the curvature in the extension region.
